(19) United States
(12) Patent Application Publication
(10) Pub. No.: US 2024/0170503 A1
(43) Pub. Date: May 23, 2024

(54) Array Substrate, Liquid Crystal Display Panel and Display Apparatus

(71) Applicants: Ordos Yuansheng Optoelectronics Co., Ltd., Ordos, Inner Mongolia (CN); BOE Technology Group Co., Ltd., Beijing (CN)

(72) Inventors: Haoyi XIN, Beijing (CN); Wei LI, Beijing (CN); Yanfeng LI, Beijing (CN); Jingjing XU, Beijing (CN); Min ZHANG, Beijing (CN); Rui FAN, Beijing (CN); Chenrong QIAO, Beijing (CN); Xiao YAN, Beijing (CN); Zhao LIU, Beijing (CN); Jing LI, Beijing (CN); Jianxiong FAN, Beijing (CN); Shangpeng LIU, Beijing (CN); Haidong SU, Beijing (CN)

(21) Appl. No.: 18/283,823

(22) PCT Filed: Oct. 31, 2022
(86) PCT No.: PCT/CN2022/128739

§ 371 Date: Sep. 25, 2023

(30) Foreign Application Priority Data
Mar. 11, 2022 (CN) 202210238472.5

(51) Int. Cl. H01L 27/12; G02F 1/1362

(52) U.S. Cl. CPC H01L 27/1248; G02F 1/136209; G02F 1/136222; G02F 1/136286; H01L 27/124

(57) ABSTRACT

An array substrate, a liquid crystal display panel and a display apparatus. The array substrate comprises: a substrate (10), a first insulating layer (20), a second insulating layer (30), a third insulating layer (40), a planarization layer (50), a first electrode layer (90A), a fourth insulating layer (70) and a second electrode layer (90B), the third insulating layer comprises a first interlayer insulating layer (40A), a second interlayer insulating layer (40B) and a third interlayer insulating layer (40C), which are sequentially stacked; the first interlayer insulating layer is located on the side of the second interlayer insulating layer close to the substrate (10), the third interlayer insulating layer is located on the side of the second interlayer insulating layer away from the substrate; the material of the first interlayer insulating layer and third interlayer insulating layer comprises silicon oxide, the material of the second interlayer insulating layer comprises silicon nitride.

### CROSS-REFERENCE TO RELATED APPLICATIONS

The present application is a U.S. National Phase Entry of International Application No. PCT/CN2022/128739 having an international filing date of Oct. 31, 2022, which claims priority of Patent Application No. 202210238472.5 filed to the CNIPA on Mar. 11, 2022 and entitled “Array Substrate, Liquid Crystal Display Panel and Display Apparatus”. The above-identified applications are hereby incorporated into the present application by reference in their entireties.

### TECHNICAL FIELD

The present disclosure relates to, but is not limited to, the field of display technologies, and more particularly, to an array substrate, a liquid crystal display panel, and a display device.

### BACKGROUND

Liquid Crystal Display (LCD for short) has advantages, such as small size, low power consumption, and no radiation, and has developed rapidly. A liquid crystal display panel includes a Thin Film Transistor (TFT for short) array substrate and a Color Filter (CF for short) substrate that are in a form of cell. Liquid Crystal (LC for short) molecules are provided between the array substrate and the color filter substrate. By controlling a common electrode and a pixel electrode, an electric field for driving the liquid crystal to deflect is formed, thereby implementing gray scale display.

### SUMMARY

The following is a summary of subject matters described in the present disclosure in detail. The summary is not intended to limit the protection scope of claims.

In a first aspect, the present disclosure provides an array substrate, including a base substrate, and a first insulation layer, a second insulation layer, a third insulation layer, a planarization layer, a first electrode layer, a fourth insulation layer and a second electrode layer, that are stacked sequentially on the base substrate.

The third insulation layer includes a first interlayer insulation layer, a second interlayer insulation layer, and a third interlayer insulation layer that are sequentially stacked; the first interlayer insulation layer is located on a side of the second interlayer insulation layer close to the base substrate, and the third interlayer insulation layer is located on a side of the second interlayer insulation layer away from the base substrate.

A material of the first interlayer insulation layer and a material of the third interlayer insulation layer include silicon oxide; and a material of the second interlayer insulation layer includes silicon nitride.

In an exemplary implementation, a thickness of the first interlayer insulation layer is in a range of 1,980 angstroms to 2,420 angstroms; a thickness of the second interlayer insulation layer is in a range of 1,260 to 1,540 angstroms; and a thickness of the third interlayer insulation layer is in a range of 855 angstroms to 1,045 angstroms.

In an exemplary implementation, the second insulation layer includes a first sub-insulation layer and a second sub-insulation layer, the second sub-insulation layer is located on a side of the first sub-insulation layer away from the base substrate; a material of the first sub-insulation layer includes silicon oxide; and a material of the second sub-insulation layer includes silicon nitride.

In an exemplary implementation, a thickness of the first sub-insulation layer is in a range of 720 angstroms to 880 angstroms, and a thickness of the second sub-insulation layer is in a range of 360 angstroms to 440 angstroms.

In an exemplary implementation, the first insulation layer includes a first buffer layer; a material of the first buffer layer includes silicon oxide; and a thickness of the first buffer layer is in a range of 2,700 angstroms to 3,300 angstroms.

In an exemplary implementation, the first insulation layer further includes a second buffer layer; the second buffer layer is located between the base substrate and the first buffer layer; and a material of the second buffer layer includes silicon nitride.

In an exemplary implementation, the first electrode layer includes a pixel electrode, and the second electrode layer includes a common electrode; an orthographic projection of the pixel electrode on the base substrate is overlapped with an orthographic projection of the common electrode on the base substrate.

In an exemplary implementation, a material of the first electrode layer and a material of the second electrode layer are same and include indium tin oxide (ITO).

In a second aspect, the present disclosure also provides a liquid crystal display panel, including a color filter substrate and the aforementioned array substrate disposed oppositely, and a liquid crystal layer located between the color filter substrate and the array substrate.

In an exemplary implementation, the liquid crystal layer includes a liquid crystal material, wherein the liquid crystal material has a birefringence of 0.09 to 0.13; and a clearing point of the liquid crystal material is greater than or equal to 100° C.

In an exemplary implementation, the color filter substrate includes a black matrix layer and a light filter layer; the black matrix layer includes a black matrix, and the light filter layer includes a light filter unit; the color filter substrate includes a pixel opening region; the pixel opening region is provided to be surrounded by the black matrix; the light filter unit covers the pixel opening region; wherein an orthographic projection of the black matrix on the base substrate is partially overlapped with an orthographic projection of a pixel electrode on the base substrate.

In an exemplary implementation, the orthographic projection of the black matrix on the base substrate is partially overlapped with an orthographic projection of a common electrode on the base substrate.

In an exemplary implementation, the common electrode includes multiple slits, and orthographic projections of the multiple slits on the base substrate have no overlapping region with the orthographic projection of the black matrix on the base substrate, and have an overlapping region with the orthographic projection of the pixel electrode on the base substrate.

In an exemplary implementation, the light filter layer includes a blue light filter unit, a green light filter unit, and a red light filter unit.

A wavelength corresponding to a transmittance peak value of the blue light filter unit is in a range of 445 nm to 465 nm; a wavelength corresponding to a half-transmittance peak value of the blue light filter unit is in a range of 378 nm to 388 nm, and a wavelength corresponding to another half-transmittance peak value of the blue light filter unit is in a range of 509 nm to 519 nm.

In an exemplary implementation, a wavelength corresponding to a transmittance peak value of the green light filter unit is in a range of 523 nm to 533 nm; a wavelength corresponding to a half-transmittance peak value of the green light filter unit is in a range of 473 nm to 483 nm, and a wavelength corresponding to another half-transmittance peak value of the green light filter unit is in a range of 598 nm to 608 nm.

In a third aspect, the present disclosure also provides a display device, including a backlight source and the aforementioned liquid crystal display panel.

In an exemplary implementation, a wavelength of a light emitting main peak of the backlight source is in a range of 445 nm to 465 nm; and a wavelength of a light emitting auxiliary peak of the backlight source is in a range of 480 nm to 600 nm.

In an exemplary implementation, the display device is a projection display device.

Other aspects may be understood upon reading and understanding the drawings and detailed description.

### BRIEF DESCRIPTION OF DRAWINGS

Accompanying drawings are used to provide understanding of technical solutions of the present disclosure and form a part of the specification. They are used for explaining the technical solutions of the present disclosure together with embodiments of the present disclosure, but do not form a limitation on the technical solutions of the present disclosure.

FIG. 1 is a schematic diagram of refraction and reflection of light between film layers.

FIG. 2 is a schematic diagram of a planar structure of an array substrate provided by an embodiment of the present disclosure.

FIG. 3 is a cross-sectional view of an array substrate provided by an embodiment of the present disclosure.

FIG. 4 is a cross-sectional view of an array substrate provided by an exemplary embodiment.

FIG. 5 is a cross-sectional view of an array substrate provided by another exemplary embodiment.

FIG. 6 is a cross-sectional view of an array substrate provided by yet another exemplary embodiment.

FIG. 7 is a transmittance comparison diagram of multiple array substrates.

FIG. 8 is a transverse color difference comparison diagram of multiple array substrates.

FIG. 9 is a longitudinal color difference comparison diagram of multiple array substrates.

FIG. 10 is a schematic diagram of a structure of a liquid crystal display panel.

FIG. 11 is a cross-sectional view of a liquid crystal display panel provided by an embodiment of the present disclosure.

FIG. 12 is a first cross-sectional view of a liquid crystal display panel provided by an exemplary embodiment.

FIG. 13 is a second cross-sectional view of a liquid crystal display panel provided by an exemplary embodiment.

FIG. 14 is a third cross-sectional view of a liquid crystal display panel provided by an exemplary embodiment.

FIG. 15 is a first schematic diagram of a structure of an array substrate provided by an embodiment of the present disclosure.

FIG. 16 is a second schematic diagram of a structure of an array substrate provided by an embodiment of the present disclosure.

FIG. 17 is a first schematic diagram of a structure of a liquid crystal display panel provided by an embodiment of the present disclosure.

FIG. 18 is a second schematic diagram of a structure of a liquid crystal display panel provided by an embodiment of the present disclosure.

### DETAILED DESCRIPTION

The present disclosure describes multiple embodiments, but the description is exemplary rather than restrictive. For those of ordinary skills in the art, there may be more embodiments and implementations in the scope of the embodiments described in the present disclosure. Although many possible combinations of features are shown in the accompanying drawings and discussed in specific implementations, many other combinations of the disclosed features are also possible. Unless expressly limited, any feature or element of any embodiment may be used in combination with, or may replace, any other feature or element in any other embodiment.

The present disclosure includes and conceives combinations with the features and elements known to those of ordinary skills in the art. The embodiments, features and elements that have been disclosed in the present disclosure may also be combined with any conventional features or elements to form technical solutions defined by the claims. Any features or elements of any embodiment may also be combined with features or elements from other technical solutions to form another technical solution defined by the claims. Therefore, it should be understood that any of the features shown and/or discussed in the present disclosure may be implemented alone or in any suitable combination. Therefore, the embodiments are not to be limited except the limitations by the appended claims and equivalents thereof. Furthermore, various modifications and variations may be made within the protection scope of the appended claims.

Unless otherwise defined, the technical or scientific terms used in the present disclosure shall have the ordinary meanings understood by those of ordinary skills in the art to which the present disclosure pertains. The “first”, “second” and similar terms used in the present disclosure do not indicate any order, quantity, or importance, but are used only for distinguishing different components. Terms such as “include” or “contain” or the like mean that an element or an object appearing before the term includes elements or objects listed after the term or their equivalents and other elements or objects are not excluded. “Connect”, “couple”, or a similar term is not limited to a physical or mechanical connection, but may include an electrical connection, whether direct or indirect. Terms such as “up”, “down”, “left” or “right” are only used to indicate relative positional relationship, and when an absolute position of a described object is changed, the relative positional relationship may also change correspondingly.

High-standard screen display effect can bring an ultimate visual experience. In the mobile phone market where the picture quality of organic light emitting diodes is king, improving the display effect, especially the transmittance, of the LCD is very important except the advantages of flicker-free and low power consumption of LCD.

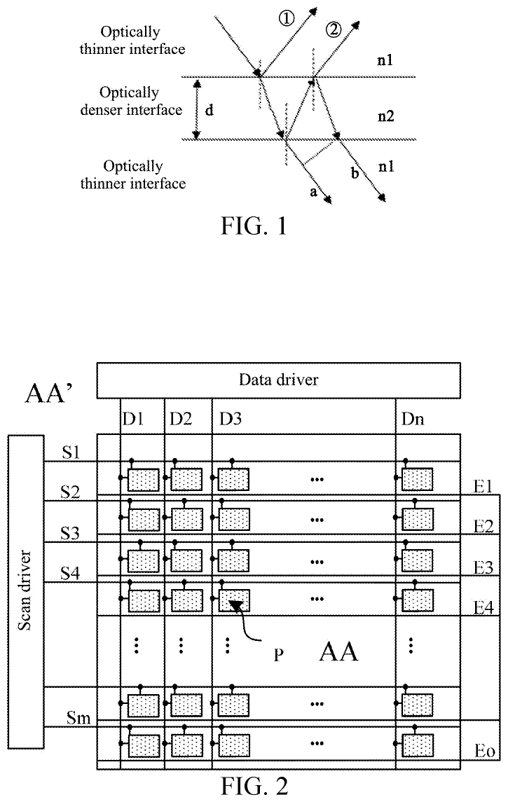

The array substrate in LCD display products has a film layer stack structure. FIG. 1 is a schematic diagram of refraction and reflection of light between film layers. As shown in FIG. 1, when light propagates in different film layers of an array substrate, reflected light and refracted light will be generated due to a difference between a refractive index n and an extinction coefficient k of each layer of materials. Refracted light \textcircled{2} at different interfaces interferes with reflected light \textcircled{1}. When coherence subtraction occurs, reflected light decreases, achieving a low reflection effect. When refracted light a interferes with refracted light b: when an optical path difference between them is an even multiple of half wavelength, coherence enhancement occurs and a transmittance of the film layer increases; when the optical path difference between them is an odd multiple of half wavelength, coherence subtraction occurs and a transmittance of the film layer decreases. Therefore, a film layer transmittance of an array substrate is related to a refractive index and thickness of each film layer. According to a research of the inventor, it is found that the film layer stack structure of an existing array substrate causes that a transmittance of the array substrate is about 77% under irradiation of 380-780 nm in the visible light band, that is to say, the transmittance of the existing array substrate is low, which reduces the display effect of the liquid crystal display product.

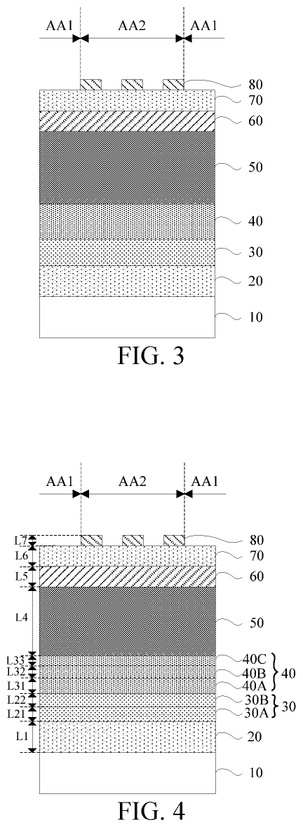

FIG. 2 is a schematic diagram of a planar structure of an array substrate provided by an embodiment of the present disclosure, and FIG. 3 is a cross-sectional view of an array substrate provided by an embodiment of the present disclosure. As shown in FIG. 2 and FIG. 3, an array substrate provided by an embodiment of the present disclosure includes a display area AA and a non-display area AA′, the display area includes a drive area AA1 and a non-drive area AA2, the drive area includes a thin film transistor, scan lines S1 to Sm configured to provide drive signals to the thin film transistors, and data lines D1 to Dn configured to provide data signals to the thin film transistors. The array substrate located in the non-drive area includes a base substrate 10, and a first insulation layer 20, a second insulation layer 30, a third insulation layer 40, a planarization layer 50, a first electrode layer 60, a fourth insulation layer 70 and a second electrode layer 80 that are stacked sequentially on the base substrate. A transmittance of the non-drive area AA2 is greater than a threshold transmittance.

In an exemplary embodiment, the base substrate 10 may be a rigid base substrate or a flexible base substrate, wherein the rigid base substrate may be, but is not limited to, one or more of glass and metal foils; and the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. Exemplarily, the base substrate 10 may be a glass base substrate.

In an exemplary embodiment, a thin film transistor may include an active layer, a gate electrode, and a source-drain electrode. Exemplarily, a structure of the thin film transistor may be a top gate structure or a bottom gate structure, which is not limited by an embodiment of the present disclosure.

In an exemplary embodiment, a spacing between a source electrode and a drain electrode may be about 10 nanometers to 50 microns, and heights of the source electrode and the drain electrode may be about 10 nanometers to 20 microns.

In an exemplary embodiment, multiple scan lines may be extended horizontally and sequentially provided along a vertical direction, multiple data lines may be extended vertically and sequentially provided along a horizontal direction, and the multiple scan lines and the multiple data lines that intersected with each other define multiple pixel areas that are regularly arranged.

In an exemplary embodiment, at least one pixel area may include a thin film transistor, a pixel electrode, and a common electrode, wherein the thin film transistor is connected with a scan line, a data line and a pixel electrode, respectively.

In an exemplary embodiment, as shown in FIG. 2, the array substrate may further include multiple common electrode lines (E1 to Eo), the multiple common electrode lines may extend along the horizontal direction and are sequentially provided along the vertical direction, and the multiple common electrode lines are connected correspondingly with common electrodes in the multiple pixel areas.

In an exemplary embodiment, the array substrate may be an array substrate in an Advanced Super Dimension Switch (ADS for short) display mode.

In an exemplary embodiment, the non-display area may be provided with a scan driver and a data driver.

In an exemplary embodiment, the multiple scan lines are led out to the non-display area and connected with the scan driver; the multiple data lines are led out to the non-display area and connected with the data driver; and at least a portion of the scan driver and the data driver may be formed on the array substrate.

In an exemplary embodiment, an external control device (such as a timing controller) may provide a gray scale value and a control signal suitable for a specification of the data driver to the data driver, and the data driver may utilize the received gray scale value and control signal to generate data voltages to be provided to the data signal lines D1, D2, D3, . . . and Dn. For example, the data driver may sample the gray scale value by using the clock signal, and apply data voltages corresponding to gray scale values to the data signal lines D1 to Dn by taking a pixel row as a unit, wherein n may be a natural number. The external control device may provide a clock signal, a scan starting signal, etc. suitable for a specification of the scan driver to the scan driver, and the scan driver may utilize the clock signal, the scan starting signal, etc. to generate scan signals to be provided to the scan signal lines S1, S2, S3, . . . and Sm. For example, the scan driver may provide sequentially a scan signal with a turn-on level pulse to the scan signal lines S1 to Sm, where m may be a nature number. For example, the scan driver may be constructed in a form of a shift register and may generate a scan signal in a manner of transmitting sequentially a scan starting signal provided in a form of a turn-on level pulse to a next-stage circuit under control of a clock signal.

In an exemplary embodiment, the threshold transmittance is 80%. In an exemplary embodiment, a transmittance of the non-drive area in the array substrate is 82.4%.

The array substrate provided by an embodiment of the present disclosure includes a display area and a non-display area, the display area includes a drive area and a non-drive area, the drive area includes a thin film transistor, a scan line configured to provide a drive signal to the thin film transistor and a data line configured to provide a data signal to the thin film transistor, the array substrate located in the non-drive area includes a base substrate, and a first insulation layer, a second insulation layer, a third insulation layer, a planarization layer, a first electrode layer, a fourth insulation layer and a second electrode layer that are stacked sequentially on the substrate, a transmittance of the non-drive area is greater than the threshold transmittance. The film layer stack structure of the array substrate provided by an embodiment of the present disclosure makes the transmittance of the non-drive area greater than the threshold transmittance.

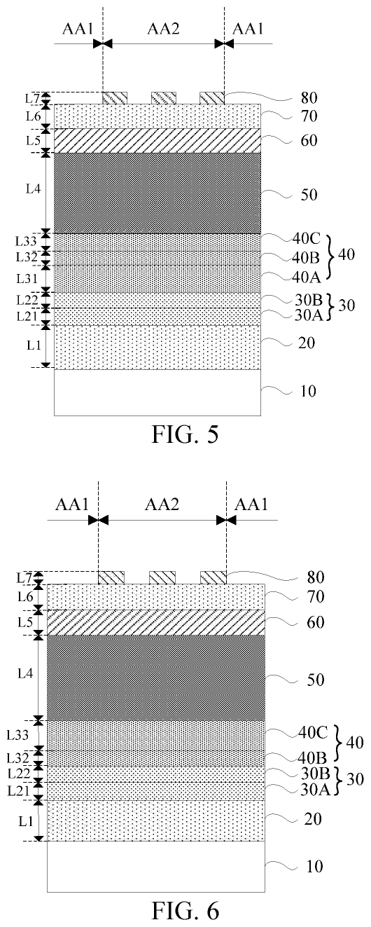

FIG. 4 is a cross-sectional view of an array substrate provided by an exemplary embodiment, FIG. 5 is a cross-sectional view of an array substrate provided by another exemplary embodiment, and FIG. 6 is a cross-sectional view of an array substrate provided by yet another exemplary embodiment. As shown in FIGS. 4 to 6, in the array substrate provided by an exemplary embodiment, the first insulation layer 20 is a single-layer structure, the thickness L1 of the first insulation layer 20 is greater than a thickness L7 of the second electrode layer 80, and the refractive index of the first insulation layer 20 is greater than the refractive index of the base substrate 10.

In an exemplary embodiment, the thickness L1 of the first insulation layer 10 is about 7.5 to 9.8 times the thickness L7 of the second electrode layer 80.

In an exemplary embodiment, the thickness L1 of the first insulation layer 10 is about 2,950 angstroms to 3,950 angstroms.

In an exemplary embodiment, a manufacturing material of the first insulation layer 10 includes: silicon oxide.

In an exemplary embodiment, as shown in FIG. 4, when the thickness L1 of the first insulation layer 20 is greater than 2,950 angstroms to 3,600 angstroms, the third insulation layer 40 may include a first interlayer insulation layer 40A, a second interlayer insulation layer 40B, and a third interlayer insulation layer 40C that are stacked sequentially. Among them, the first interlayer insulation layer 40A is located on a side of the second interlayer insulation layer 40B close to the base substrate, and the third interlayer insulation layer 40C is located on a side of the second interlayer insulation layer 40B away from the base substrate.

In an exemplary embodiment, a thickness L31 of the first interlayer insulation layer 40A may be greater than a thickness L32 of the second interlayer insulation layer 40B.

In an exemplary embodiment, the thickness L32 of the second interlayer insulation layer 40B is greater than a thickness L33 of the third interlayer insulation layer 40C.

In an exemplary embodiment, a refractive index of the first interlayer insulation layer 40A is smaller than a refractive index of the second interlayer insulation layer 40B.

In an exemplary embodiment, a refractive index of the third interlayer insulation layer 40C is smaller than the refractive index of the second interlayer insulation layer 40B.

In an exemplary embodiment, the refractive index of the second interlayer insulation layer 40B is greater than a refractive index of the base substrate.

In an exemplary embodiment, the thickness L31 of the first interlayer insulation layer 40A may be about 1.1 to 1.2 times the thickness of the second interlayer insulation layer 40B.

In an exemplary embodiment, the thickness L32 of the second interlayer insulation layer 40B is about 3.2 to 3.5 times the thickness of the third interlayer insulation layer 40C.

In an exemplary embodiment, the thickness L33 of the third interlayer insulation layer 40C is about 0.9 to 1.1 times the thickness of the second electrode layer.

In an exemplary embodiment, the thickness L31 of the first interlayer insulation layer 40A may be about 1,500 angstroms to 1,700 angstroms. Exemplarily, the thickness of the first interlayer insulation layer 40A may be 1,600 angstroms.

In an exemplary embodiment, the thickness L32 of the second interlayer insulation layer 40B may be about 1,330 to 1,470 angstroms. Exemplarily, the thickness of the second interlayer insulation layer 40B may be 1,400 angstroms.

In an exemplary embodiment, the thickness of the third interlayer insulation layer 40C may be about 380 angstroms to 420 angstroms. Exemplarily, the thickness of the third interlayer insulation layer 40C may be 400 angstroms.

In an exemplary embodiment, as shown in FIG. 4, illustration is made by taking a case in which the first insulation layer 10 has a thickness of 3,000 angstroms, the first interlayer insulation layer 40A has a thickness of 1,600 angstroms, the second interlayer insulation layer 40B has a thickness of 1,400 angstroms, and the third interlayer insulation layer 40C has a thickness of 400 angstroms as an example.

In an exemplary embodiment, as shown in FIG. 4, the manufacturing material of the first interlayer insulation layer 40A and the third interlayer insulation layer 40C may include: silicon oxide.

In an exemplary embodiment, as shown in FIG. 4, the manufacturing material of the second interlayer insulation layer 40B may include: silicon nitride.

In an exemplary embodiment, as shown in FIG. 5, when the thickness L1 of the first insulation layer 10 is greater than 3,885 angstroms, the third insulation layer 40 may include a first interlayer insulation layer 40A, a second interlayer insulation layer 40B, and a third interlayer insulation layer 40C stacked sequentially. Herein, the first interlayer insulation layer 40A is located on a side of the second interlayer insulation layer 40B close to the base substrate 10, and the third interlayer insulation layer 40C is located on a side of the second interlayer insulation layer 40B away from the base substrate 10.

In an exemplary embodiment, as shown in FIG. 5, the thickness of the first interlayer insulation layer 40A may be greater than the thickness of the second interlayer insulation layer 40B.

In an exemplary embodiment, the thickness of the second interlayer insulation layer 40B may be less than the thickness of the third interlayer insulation layer 40C.

In an exemplary embodiment, the refractive index of the first interlayer insulation layer 40A is smaller than the refractive index of the second interlayer insulation layer 40B.

In an exemplary embodiment, the refractive index of the third interlayer insulation layer 40C is smaller than the refractive index of the second interlayer insulation layer 40B.

In an exemplary embodiment, the refractive index of the second interlayer insulation layer 40B is greater than the refractive index of the base substrate 10.

In an exemplary embodiment, the thickness of the first interlayer insulation layer 40A may be about 1.7 to 1.8 times the thickness of the second interlayer insulation layer 40B.

In an exemplary embodiment, the thickness of the third interlayer insulation layer 40C may be about 1.05 to 1.1 times the thickness of the second interlayer insulation layer 40B.

In an exemplary embodiment, the thickness of the second interlayer insulation layer 40B may be about 3.3 to 3.7 times the thickness of the second electrode layer.

In an exemplary embodiment, the thickness L31 of the first interlayer insulation layer 40A may be about 2,280 angstroms to 2,520 angstroms. Exemplarily, the thickness L31 of the first interlayer insulation layer 40A may be 2400 angstroms.

In an exemplary embodiment, the thickness of the second interlayer insulation layer 40B may be 1,330 to 1,470 angstroms. Exemplarily, the thickness L32 of the second interlayer insulation layer 40B may be 1,400 angstroms.

In an exemplary embodiment, the thickness L33 of the third interlayer insulation layer 40C may be about 1,420 angstroms to 1,080 angstroms. Exemplarily, the thickness L33 of the third interlayer insulation layer 40C is 1,500 angstroms.

In an exemplary embodiment, as shown in FIG. 5, illustration is made by taking a case in which the first insulation layer 10 has a thickness L1 of 3,900 angstroms, the first interlayer insulation layer 40A has a thickness L31 of 2,400 angstroms, the second interlayer insulation layer 40B has a thickness L32 of 1,400 angstroms, and the third interlayer insulation layer 40C has a thickness L33 of 1,500 angstroms as an example.

In an exemplary embodiment, as shown in FIG. 5, the manufacturing material of the first interlayer insulation layer 40A and the third interlayer insulation layer 40C may include: silicon oxide.

In an exemplary embodiment, as shown in FIG. 5, the manufacturing material of the second interlayer insulation layer 40B may include: silicon nitride.

In an exemplary embodiment, as shown in FIG. 6, when the thickness L1 of the first insulation layer 10 is greater than or equal to 3,500 angstroms and less than 3,885 angstroms, the third insulation layer 40 may include a second interlayer insulation layer 40B and a third interlayer insulation layer 40C stacked sequentially; the second interlayer insulation layer 40B is located on a side of the third interlayer insulation layer 40C close to the base substrate.

In an exemplary embodiment, as shown in FIG. 6, the thickness L33 of the third interlayer insulation layer 40C may be greater than the thickness L32 of the second interlayer insulation layer 40B.

In an exemplary embodiment, as shown in FIG. 6, the thickness L33 of the second interlayer insulation layer 40B may be greater than the thickness L7 of the second electrode layer.

In an exemplary embodiment, the refractive index of the third interlayer insulation layer 40C may be less than the refractive index of the second interlayer insulation layer 40B.

In an exemplary embodiment, the refractive index of the second interlayer insulation layer 40B may be greater than the refractive index of the base substrate.

In an exemplary embodiment, the thickness of the third interlayer insulation layer 40C may be about 1.7 to 1.8 times the thickness of the second interlayer insulation layer 40B.

In an exemplary embodiment, the thickness of the second interlayer insulation layer 40B may be about 3.3 to 3.7 times the thickness of the second electrode layer.

In an exemplary embodiment, the thickness of the second interlayer insulation layer 40B is about 1,330 to 1,470 angstroms. Exemplarily the thickness of the second interlayer insulation layer 40B is 1,400 angstroms.

In an exemplary embodiment, the thickness of the third interlayer insulation layer 40C is about 2,280 angstroms to 2,520 angstroms. Exemplarily, the thickness of the third interlayer insulation layer 40C is 2,400 angstroms.

In an exemplary embodiment, as shown in FIG. 6, illustration is made by taking a case in which the first insulation layer has a thickness of 3,700 angstroms, the second interlayer insulation layer 40B has a thickness of 1,400 angstroms, and the third interlayer insulation layer 40C has a thickness of 2,400 angstroms as an example.

In an exemplary embodiment, as shown in FIG. 6, the manufacturing material of the second interlayer insulation layer 40B may include: silicon nitride.

In an exemplary embodiment, as shown in FIG. 6, the manufacturing material of the third interlayer insulation layer 40C may include: silicon oxide.

In an exemplary embodiment, the first electrode layer may be a transparent conductive layer.

In an exemplary embodiment, the second electrode layer may be a transparent conductive layer.

In an exemplary embodiment, as shown in FIGS. 4 to 6, the second insulation layer 30 in the array substrate includes a first sub-insulation layer 30A and a second sub-insulation layer 30B. The second sub-insulation layer 30B is located on a side of the first sub-insulation layer 30A away from the base substrate 10.

In an exemplary embodiment, as shown in FIGS. 4 to 6, a thickness L21 of the first sub-insulation layer 30A may be greater than a thickness L22 of the second sub-insulation layer 30B, and may be greater than the thickness L7 of the second electrode layer 80.

In an exemplary embodiment, a thickness L5 of the first electrode layer 60 may be greater than the thickness L7 of the second electrode layer 80.

In an exemplary embodiment, a thickness L6 of the fourth insulation layer 70 may be greater than the thickness L7 of the second electrode layer 80.

In an exemplary embodiment, a thickness L4 of the planarization layer 50 may be greater than the thickness L5 of the first electrode layer 60.

In an exemplary embodiment, the thickness L21 of the first sub-insulation layer 30A may be about 1.8 to 2.2 times the thickness L22 of the second sub-insulation layer 30B.

In an exemplary embodiment, the thickness L22 of the second sub-insulation layer 30B may be about 0.9 to 1.1 times the thickness L7 of the second electrode layer 80.

In an exemplary embodiment, the thickness L5 of the first electrode layer 60 may be about 1.8 to 2.2 times the thickness L7 of the second electrode layer 80.

In an exemplary embodiment, the thickness L6 of the fourth insulation layer 70 may be about 1.8 to 2.2 times the thickness L7 of the second electrode layer 80. The thickness L6 of the fourth insulation layer 70 may be about 0.9 to 1.1 times the thickness L5 of the first electrode layer 60.

In an exemplary embodiment, the thickness L4 of the planarization layer 50 may be about 28.5 to 29 times the thickness L5 of the first electrode layer 60.

In an exemplary embodiment, the thickness L21 of the first sub-insulation layer 30A may be about 760 angstroms to 840 angstroms. Exemplarily, the thickness L21 of the first sub-insulation layer 30A is 800 angstroms.

In an exemplary embodiment, the thickness L22 of the second sub-insulation layer 30B is about 380 angstroms to 420 angstroms. Exemplarily, the thickness L22 of the second sub-insulation layer 30B may be 400 angstroms.

In an exemplary embodiment, the thickness L4 of the planarization layer 50 is about 21,850 angstroms to 24,150 angstroms. Exemplarily, the thickness L4 of the planarization layer 50 may be 23,000 angstroms.

In an exemplary embodiment, the thickness L5 of the first electrode layer 60 is about 760 angstroms to 840 angstroms. Exemplarily, the thickness L5 of the first electrode layer 60 may be 800 angstroms.

In an exemplary embodiment, the thickness L6 of the fourth insulation layer 70 is about 760 angstroms to 840 angstroms. Exemplarily, the thickness L6 of the fourth insulation layer 70 may be 800 angstroms.

In an exemplary embodiment, the thickness L7 of the second electrode layer 80 is about 380 angstroms to 420 angstroms. Exemplarily, the thickness L7 of the second electrode layer 80 may be 400 angstroms.

In an exemplary embodiment, as shown in FIGS. 4-6, illustration is made by taking a case in which the first sub-insulation layer 30A has a thickness L21 of 800 angstroms, the second sub-insulation layer 30B has a thickness L22 of 400 angstroms, the planarization layer 50 has a thickness L4 of 23,000 angstroms, the first electrode layer 60 has a thickness L5 of 800 angstroms, the fourth insulation layer 70 has a thickness L6 of 800 angstroms, and the second electrode layer 80 has a thickness L7 of 400 angstroms as an example.

In an exemplary embodiment, a refractive index of the first sub-insulation layer 30A may be less than a refractive index of the second sub-insulation layer 30B.

In an exemplary embodiment, the refractive index of the first sub-insulation layer 30A is greater than the refractive index of the base substrate 10.

In an exemplary embodiment, a refractive index of the planarization layer 50 is greater than the refractive index of the base substrate 10.

In an exemplary embodiment, a refractive index of the second electrode layer 80 is greater than the refractive index of the planarization layer 50.

In an exemplary embodiment, a refractive index of the fourth insulation layer 70 is greater than the refractive index of the second electrode layer 80 and a refractive index of the first electrode layer 60.

In an exemplary embodiment, a manufacturing material of the first sub-insulation layer 30A may include: silicon oxide.

In an exemplary embodiment, a manufacturing material of the second sub-insulation layer 30B may include: silicon nitride.

In an exemplary embodiment, a manufacturing material of the fourth insulation layer 70 may include: silicon oxide.

In an exemplary embodiment, a manufacturing material of the first electrode layer 60 and the second electrode layer 80 may include: indium tin oxide.

In an exemplary embodiment, an array substrate includes: multiple pixel areas located in a display area, each pixel area includes: a first electrode and a second electrode, and an orthographic projection of the first electrode located in a same pixel area on the base substrate 10 is at least partially overlapped with an orthographic projection of the second electrode on the base substrate 10.

In an exemplary embodiment, the first electrode layer 60 may include: a first electrode of at least one pixel area. The first electrode may be a common electrode.

In an exemplary embodiment, the first electrode is a planar electrode.

In an exemplary embodiment, the second electrode layer 80 includes: a second electrode of at least one pixel area. The second electrode may be a pixel electrode.

In an exemplary embodiment, the second electrode may include: multiple sub-electrodes arranged in an array. The sub-electrode may be a block electrode.

In an exemplary embodiment, the array substrate located in the drive area may include: a base substrate 10, and a first insulation layer 20, a semiconductor layer, a second insulation layer 30, a first conductive layer, a third insulation layer 40, a second conductive layer, a planarization layer 50, a first electrode layer 60, and a fourth insulation layer 70 that are stacked sequentially on the base substrate 10.

In an exemplary embodiment, the semiconductor layer may include: an active layer of a thin film transistor.

In an exemplary embodiment, the first conductive layer may include: a gate electrode of a thin film transistor and a scan line.

In an exemplary embodiment, the second conductive layer may include: a source-drain electrode of a thin film transistor and a data line.

In an exemplary embodiment, the semiconductor layer may be an amorphous silicon layer, a polycrystalline silicon layer, or may be a metal oxide layer. Herein, the metal oxide layer may be made of an oxide containing indium and tin, an oxide containing tungsten and indium, an oxide containing tungsten, indium and zinc, an oxide containing titanium and indium, an oxide containing titanium, indium and tin, an oxide containing indium and zinc, an oxide containing silicon, indium and tin or an oxide containing indium or gallium and zinc. The metal oxide layer may be a single layer, double layers or multi layers.

In an exemplary embodiment, the first conductive layer and the second conductive layer may be made of a metal material, such as any one or more of Argentum (Ag), Copper (Cu), Aluminum (Al), and Molybdenum (Mo), or an alloy material of any of the aforementioned metals, such as an Aluminum-Neodymium alloy (AlNd) or a Molybdenum-Niobium alloy (MoNb), and may be a single-layer structure, or a multi-layer composite structure such as Mo/Cu/Mo.

In an exemplary embodiment, the first insulation layer may be referred to as a buffer layer, the second insulation layer may be referred to as a gate insulation layer, the third insulation layer may be referred to as an interlayer insulation layer, and the fourth insulation layer may be referred to as a passivation layer.

Differences between the array substrate provided in FIG. 4 and the array substrate provided in FIG. 5 lie in thicknesses of the first insulation layer and the third insulation layer. A thickness of the first insulation layer in FIG. 4 is less than a thickness of the first insulation layer in FIG. 5. A thickness of the first interlayer insulation layer in FIG. 4 is less than a thickness of the first interlayer insulation layer in FIG. 5. A thickness of the second interlayer insulation layer in FIG. 4 is less than a thickness of the second interlayer insulation layer in FIG. 5. A thickness of the third interlayer insulation layer in FIG. 4 is less than a thickness of the third interlayer insulation layer in FIG. 5.

Differences between the array substrate provided in FIG. 4 and the array substrate provided in FIG. 6 lie in a structure of the third insulation layer and thicknesses of the first insulation layer and the interlayer insulation layers. The third insulation layer in FIG. 4 includes a first interlayer insulation layer to a third interlayer insulation layer, and the third insulation layer in FIG. 6 only includes a second interlayer insulation layer and a third interlayer insulation layer. A thickness of the first insulation layer in FIG. 4 is less than a thickness of the first insulation layer in FIG. 6. A thickness of the second interlayer insulation layer in FIG. 4 is equal to a thickness of the second interlayer insulation layer in FIG. 6. A thickness of the third interlayer insulation layer in FIG. 4 is less than a thickness of the third interlayer insulation layer in FIG. 6.

Differences between the array substrate provided in FIG. 5 and the array substrate provided in FIG. 6 lie in a structure of the third insulation layer and thicknesses of the first insulation layer and the interlayer insulation layers. The third insulation layer in FIG. 5 includes a first interlayer insulation layer to a third interlayer insulation layer, and the third insulation layer in FIG. 6 only includes a second interlayer insulation layer and a third interlayer insulation layer. A thickness of the first insulation layer in FIG. 5 is greater than a thickness of the first insulation layer in FIG. 6. A thickness of the second interlayer insulation layer in FIG. 5 is equal to a thickness of the second interlayer insulation layer in FIG. 6. A thickness of the third interlayer insulation layer in FIG. 5 is less than a thickness of the third interlayer insulation layer in FIG. 6.

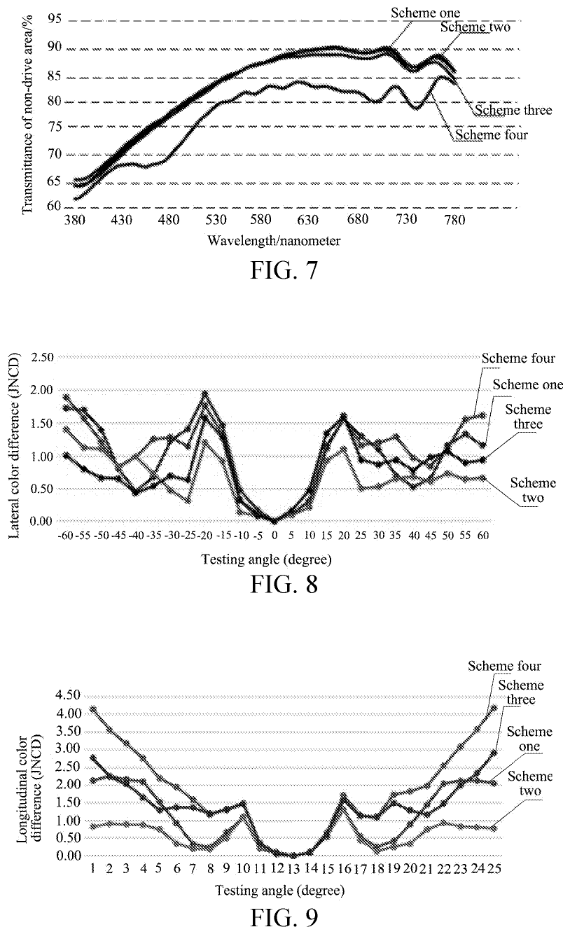

FIG. 7 is a transmittance comparison diagram of multiple array substrates. The array substrate provided by Scheme one in FIG. 7 is the array substrate provided by FIG. 4, the array substrate provided by Scheme two is the array substrate provided by FIG. 5, the array substrate provided by Scheme three is the array substrate provided by FIG. 6, and the array substrate provided by Scheme four is the existing array substrate. The first insulation layer in the existing array substrate includes a first buffer insulation layer and a second buffer insulation layer, the second insulation layer includes a first sub-insulation layer and a second sub-insulation layer, the third insulation layer includes a first interlayer insulation layer to a third interlayer insulation layer, wherein the first buffer insulation layer is made of silicon nitride with a thickness of 1,000 angstroms, the second buffer insulation layer is made of silicon oxide with a thickness of 3,000 angstroms, the first sub-insulation layer is made of silicon oxide with a thickness of 800 angstroms, the second sub-insulation layer is made of silicon nitride with a thickness of 400 angstroms, the first interlayer insulation layer is made of silicon oxide with a thickness of 2,000 angstroms, the second interlayer insulation layer is made of silicon nitride with a thickness of 1,600 angstroms, the third interlayer insulation layer is made of silicon oxide with a thickness of 1,000 angstroms, the thickness of the planarization layer is 23,000 angstroms, the thickness of the first electrode layer is 800 angstroms, the thickness of the fourth insulation layer is 800 angstroms, and the thickness of the second electrode layer is 400 angstroms.

Differences between the array substrate provided in Scheme four and the array substrate provided in FIG. 4 lie in a structure of the first insulation layer and thicknesses of the first insulation layer and the third insulation layer. A thickness of the first insulation layer in Scheme four is greater than a thickness of the first insulation layer in FIG. 4. A thickness of the first interlayer insulation layer in Scheme four is greater than a thickness of the first interlayer insulation layer in FIG. 4. A thickness of the second interlayer insulation layer in Scheme four is greater than a thickness of the second interlayer insulation layer in FIG. 4. A thickness of the third interlayer insulation layer in Scheme four is greater than a thickness of the third interlayer insulation layer in FIG. 4.

Differences between the array substrate provided in Scheme four and the array substrate provided in FIG. 5 lie in a structure of the first insulation layer and thicknesses of the first insulation layer and the third insulation layer. The thickness of the first insulation layer in Scheme four is greater than a thickness of the first insulation layer in FIG. 5. The thickness of the first interlayer insulation layer in Scheme four is less than a thickness of the first interlayer insulation layer in FIG. 5. The thickness of the second interlayer insulation layer in Scheme four is greater than a thickness of the second interlayer insulation layer in FIG. 5. The thickness of the third interlayer insulation layer in Scheme four is less than a thickness of the third interlayer insulation layer in FIG. 5.

Differences between the array substrate provided in Scheme four and the array substrate provided in FIG. 5 lie in the structure of the first insulation layer, the structure of the third insulation layer and thicknesses of the first insulation layer and the third insulation layer. The thickness of the first insulation layer in Scheme four is greater than a thickness of the first insulation layer in FIG. 5. The thickness of the second interlayer insulation layer in Scheme four is greater than a thickness of the second interlayer insulation layer in FIG. 5. The thickness of the third interlayer insulation layer in Scheme four is less than a thickness of the third interlayer insulation layer in FIG. 5.

In FIG. 7, the abscissa represents a wavelength of incident light, and the ordinate represents a transmittance of a non-drive area. After testing, as shown in FIG. 7, transmittances of Schemes one to three provided in the present disclosure are about 82.4% in the visible light band 380-780 nm, while a transmittance of Scheme four is about 77% in the visible light band 380-780 nm, and a transmittance is improved by about 7%. Herein, a transmittance in 430-780 nm band is significantly improved.

As shown in FIG. 7, a transmittance of Scheme two in band 380-480 nm is greater than a transmittance of Scheme three in visible band 380-480 nm, and a transmittance of Scheme three in band 380-480 nm is greater than a transmittance of scheme one in visible band 580-480 nm.

As shown in FIG. 7, a transmittance of Scheme three in band 480-580 nm is greater than a transmittance of Scheme two in visible band 480-580 nm, and a transmittance of Scheme two in band 480-580 nm is greater than a transmittance of Scheme one in visible band 480-580 nm.

As shown in FIG. 7, a transmittance of Scheme one in band 580-780 nm is greater than a transmittance of Scheme two in visible band 580-780 nm, and a transmittance of Scheme two in band 580-780 nm is greater than a transmittance of Scheme three in visible band 580-780 nm.

FIG. 8 is a lateral color difference comparison diagram of multiple array substrates, and FIG. 9 is a longitudinal color difference comparison diagram of multiple array substrates. As shown in FIG. 8, Schemes one to three provided by the present disclosure have a lateral color difference that is less than 3JNCD at a large view angle (a visual angle is greater than 60 degrees). A color difference of the array substrate provided by the present disclosure is superior to a color difference of the array substrate provided by Scheme four, which can ensure that the array substrate has no defects related to red and green in a large view angle, and can improve the display effect.

As shown in FIG. 8, when a visual angle is greater than 50 degrees, a lateral color difference of the array substrate provided by Scheme four is greater than any one of lateral color differences of Schemes one to three, a lateral color difference of the array substrate provided by Scheme one is greater than a lateral color difference of the array substrate provided by Scheme three, and the lateral color difference of the array substrate provided by Scheme three is greater than a lateral color difference of the array substrate provided by Scheme two. That is, when the visual angle is greater than 50 degrees, the lateral color difference of the array substrate provided by Scheme two is the smallest.

As shown in FIG. 9, the array substrates provided in Schemes one to four have the smallest longitudinal color difference when a visual angle is 13 degrees. When a visual angle is 10 to 16 degrees, longitudinal color differences of the array substrates provided by Schemes one to four are basically consistent. When visual angles are 1 to 2 degrees, 5 to 8 degrees, 16 to 20 degrees and 23 to 25 degrees, a longitudinal color difference of the array substrate provided by Scheme four is greater than a longitudinal color difference of the array substrate provided by Scheme three, a longitudinal color difference of the array substrate provided by Scheme three is greater than a longitudinal color difference of the array substrate provided by Scheme one, and a longitudinal color difference of the array substrate provided by Scheme one is greater than a longitudinal color difference of the array substrate provided by Scheme two. When visual angles are 2 to 5 degrees, 8 to 16 degrees and 20 to 23 degrees, a longitudinal color difference of the array substrate provided by Scheme four is greater than a longitudinal color difference of the array substrate provided by Scheme one, a longitudinal color difference of the array substrate provided by Scheme one is greater than a longitudinal color difference of the array substrate provided by Scheme three, and a longitudinal color difference of the array substrate provided by Scheme three is greater than a longitudinal color difference of the array substrate provided by Scheme two. Compared with Schemes one, three and four, a longitudinal color difference of the array substrate provided by Scheme two is the smallest when the visual angle is 1 degree to 25 degrees.

By changing thicknesses of the first insulation layer and the third insulation layer in the array substrate and a stack structure of the film layer, the present disclosure changes relationships of coherence enhancement and coherence subtraction between refracted light and reflected light in film layers, thereby achieving the effects of improving transmittance and improving redness in a large view angle.

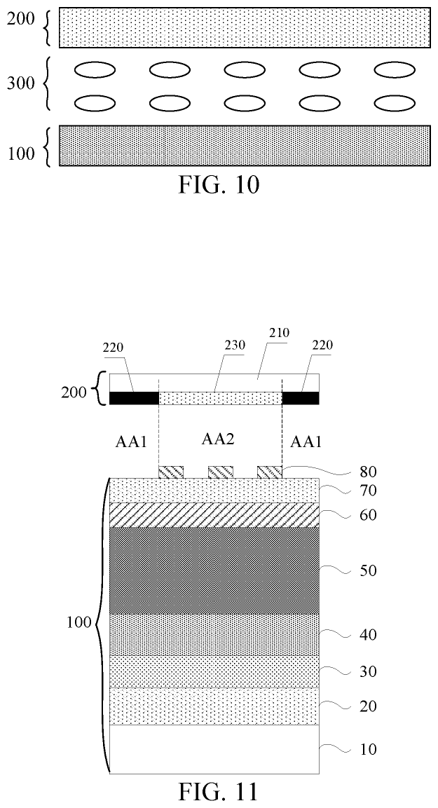

FIG. 10 is a schematic diagram of a structure of a liquid crystal display panel, and FIG. 11 is a cross-sectional view of a liquid crystal display panel provided by an embodiment of the present disclosure. As shown in FIG. 10 and FIG. 11, the liquid crystal display panel provided by an embodiment of the present disclosure includes a color filter substrate 200 and an array substrate 100 oppositely disposed, and a liquid crystal layer 300 disposed between the color filter substrate 200 and the array substrate 100.

In an exemplary embodiment, an array substrate is the array substrate provided in any of the foregoing embodiments, and the implementation principle and implementation effect thereof are similar and will not be described repeatedly herein.

In an exemplary embodiment, the liquid crystal display panel may further include a structure such as a spacer provided to support the color filter substrate and the array substrate and a frame sealing glue, which is not limited in the present disclosure.

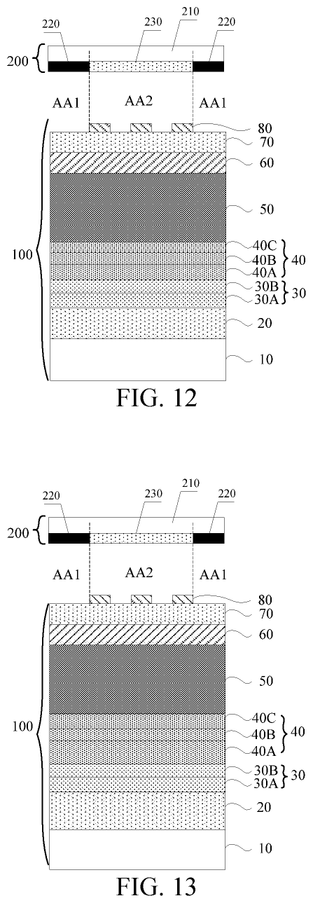

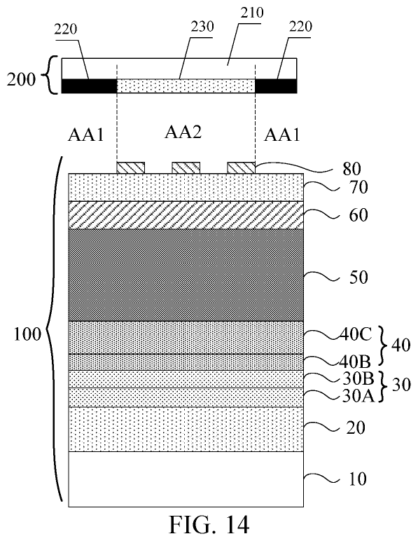

FIG. 12 is a first cross-sectional view of a liquid crystal display panel provided by an exemplary embodiment, FIG. 13 is a second cross-sectional view of a liquid crystal display panel provided by an exemplary embodiment, and FIG. 14 is a third cross-sectional view of a liquid crystal display panel provided by an exemplary embodiment. As shown in FIGS. 11 to 14, the color filter substrate 200 includes a base substrate 210, and a black matrix layer 220 and a light filter layer 230 disposed on the base substrate 210. Herein, an orthographic projection of the black matrix layer 220 on the base substrate is at least partially overlapped with an orthographic projection of the drive area AA1 on the base substrate, and an orthographic projection of the light filter layer 230 on the base substrate is at least partially overlapped with an orthographic projection of the non-drive area AA2 on the base substrate. In FIG. 12, illustration is made by taking a case in which an array substrate is the array substrate provided in FIG. 4 as an example, in FIG. 13, illustration is made by an array substrate is the array substrate provided in FIG. 5 as an example, and in FIG. 14, illustration is made by taking a case in which an array substrate is the array substrate provided in FIG. 6 as an example.

In an exemplary embodiment, the base substrate 210 may be a rigid base substrate or a flexible base substrate, wherein the rigid base substrate may be, but is not limited to, one or more of glass and metal foils; and the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. Exemplarily, the base substrate 210 may be a glass base substrate.

In an exemplary embodiment, the black matrix layer and the light filter layer may be disposed in a same layer. The black matrix layer is provided with a via, and the light filter layer is filled in the via of the black matrix layer.

In an exemplary embodiment, an orthographic projection of the black matrix layer on the base substrate may have no overlapping region with or may have an overlapping region with an orthographic projection of the light filter layer on the base substrate, which is not limited by the present disclosure.

In an exemplary embodiment, the light filter layer may include multiple light filters of different colors, and an area corresponding to each pixel area on the color filter substrate is provided with a light filter.

In an exemplary embodiment, light filters may include a red light filter, a green light filter, and a blue light filter.

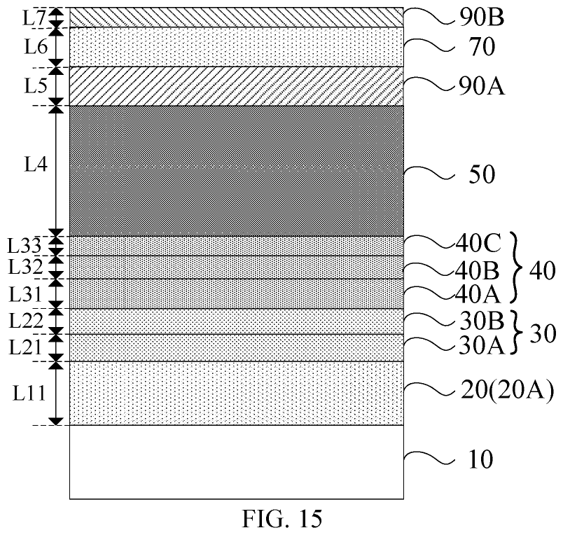

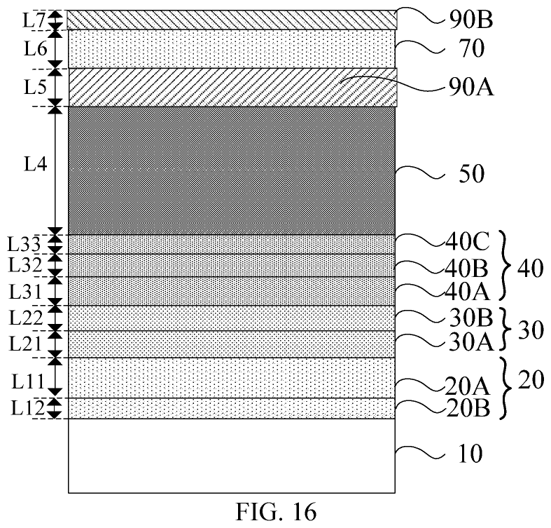

FIG. 15 is a first schematic diagram of a structure of an array substrate provided by an embodiment of the present disclosure, and FIG. 16 is a second schematic diagram of a structure of an array substrate provided by an embodiment of the present disclosure. As shown in FIG. 15 and FIG. 16, an array substrate provided by an embodiment of the present disclosure may include a base substrate 10, and a first insulation layer 20, a second insulation layer 30, a third insulation layer 40, a planarization layer 50, a first electrode layer 90A, a fourth insulation layer 70, and a second electrode layer 90B stacked sequentially on the base substrate 10. The third insulation layer 40 includes a first interlayer insulation layer 40A, a second interlayer insulation layer 40B, and a third interlayer insulation layer 40C stacked sequentially; the first interlayer insulation layer 40A is located on a side of the second interlayer insulation layer 40B close to the base substrate 10, and the third interlayer insulation layer 40C is located on a side of the second interlayer insulation layer 40B away from the base substrate 10.

In an exemplary implementation, materials of the first interlayer insulation layer 40A and the third interlayer insulation layer 40C include silicon oxide; and a material of the second interlayer insulation layer 40B includes silicon nitride.

The film layer stack structure of an array substrate provided by an embodiment of the present disclosure can make the transmittance of the array substrate higher, thereby improving a light utilization rate of the display product where the array substrate is located, and improving the display effect.

Exemplarily, the first interlayer insulation layer 40A and the third interlayer insulation layer 40C are made of silicon oxide and the second interlayer insulation layer 40B is made of silicon nitride. Silicon oxide may be expressed as SiₓO_{y}; and silicon nitride may be expressed as SiₘNₙ.

In an exemplary implementation, a thickness of the first interlayer insulation layer 40A is in the range of 1,980 angstroms to 2,420 angstroms. Exemplarily, the thickness L31 of the first interlayer insulation layer 40A may be 2,200 angstroms. A thickness of the second interlayer insulation layer 40B is in the range of 1,260 to 1,540 angstroms. Exemplarily, the thickness L32 of the second interlayer insulation layer 40B may be 1,400 angstroms. A thickness of the third interlayer insulation layer 40C is in the range of 855 angstroms to 1,045 angstroms. Exemplarily, the thickness L33 of the third interlayer insulation layer 40C may be 950 angstroms.

In an exemplary embodiment, the base substrate 10 may be a rigid base substrate or a flexible base substrate, wherein the rigid base substrate may be, but is not limited to, one or more of glass and metal foil; the flexible base substrate may be, but is not limited to, one or more of polyethylene terephthalate, ethylene terephthalate, polyether ether ketone, polystyrene, polycarbonate, polyarylester, polyarylate, polyimide, polyvinyl chloride, polyethylene, and textile fibers. Exemplarily, the base substrate may be a glass base substrate.

In an exemplary implementation, the first electrode layer 90A and the second electrode layer 90B represent only a position of film layer and do not represent a specific structure of the film layer.

In an exemplary embodiment, an array substrate may be the array substrate in an Advanced Super Dimension Switch (ADS for short) display mode.

In an exemplary implementation, refractive indices of the first interlayer insulation layer 40A and the third interlayer insulation layer 40C may be smaller than a refractive index of the second interlayer insulation layer 40B. For example, the refractive indices of the first interlayer insulation layer 40A and the third interlayer insulation layer 40C are in the range of 1.1 to 1.4; for example, the refractive index of the second interlayer insulation layer 40B may be in the range of 1.7 to 1.9. In an exemplary implementation, as shown in FIG. 15 and FIG. 16, the second insulation layer 30 may include a first sub-insulation layer 30A and a second sub-insulation layer 30B. Herein, the second sub-insulation layer 30B may be located on a side of the first sub-insulation layer 30A away from the base substrate 10.

In an exemplary implementation, as shown in FIG. 15 and FIG. 16, a material of the first sub-insulation layer 30A includes silicon oxide; a material of the second sub-insulation layer includes silicon nitride. Exemplarily, the first sub-insulation layer 30A is made of silicon oxide; the second sub-insulation layer 30B is made of silicon nitride. The material and film layer thickness of the second insulation layer 30 may cooperate with the third insulation layer to achieve a higher transmittance.

In an exemplary implementation, a thickness L21 of the first sub-insulation layer 30A is in the range of 720 angstroms to 880 angstroms. Exemplarily, the thickness L21 of the first sub-insulation layer 30A may be 800 angstroms.

In an exemplary implementation, a thickness L22 of the second sub-insulation layer 30B is in the range of 360 angstroms to 440 angstroms. Exemplarily, the thickness L22 of the second sub-insulation layer 30B may be 400 angstroms.

In an exemplary implementation, a refractive index of the first sub-insulation layer 30A is smaller than a refractive index of the second sub-insulation layer 30B. For example, the refractive index of the first sub-insulation layer 30A may be in the range of 1.3 to 1.5; for example, the refractive index of the second sub-insulation layer 30B is in the range of 1.8 to 2.1.

In an exemplary implementation, the first insulation layer 20 is a single-layer structure or a double-layer structure. In FIG. 15 illustration is made by taking a case in which the first insulation layer is a single-layer structure as an example; in FIG. 16 illustration is made by taking a case in which the first insulation layer is a double-layer structure as an example. The material and film layer thickness of the first insulation layer 20 may cooperate with the third insulation layer to achieve a higher transmittance.

In an exemplary implementation, as shown in FIG. 15, the first insulation layer 20 includes a first buffer layer 20A, and a material of the first buffer layer 20A may include silicon oxide or silicon nitride. For example, the first buffer layer 20A is made of one of silicon oxide or silicon nitride.

In an exemplary implementation, a material of the first buffer layer 20A includes silicon oxide. Exemplarily, the first buffer layer 20A is made of silicon nitride; for example, a thickness of the first buffer layer 20A is in the range of 2,700 angstroms to 3,300 angstroms. Exemplarily, the thickness of the first buffer layer 20A may be 3,000 angstroms.

In an exemplary implementation, a refractive index of the first buffer layer 20A is 1.3 to 1.5.

In an exemplary implementation, as shown in FIG. 16, the first insulation layer includes a first buffer layer 20A and a second buffer layer 20B; the second buffer layer 20B is located between the base substrate 10 and the first buffer layer 20A; a material of the second buffer layer 20A includes silicon nitride. Exemplarily, the first buffer layer 20A is made of silicon nitride. In an exemplary implementation, the thickness of the first buffer layer 20A is in the range of 2,700 angstroms to 3,300 angstroms. Exemplarily, the thickness of the first buffer layer 20A may be 3,000 angstroms. In an exemplary implementation, the refractive index of the first buffer layer 20A is 1.3 to 1.5.

In an exemplary implementation, a material of the second buffer layer 20B may include silicon nitride. Exemplarily, the second buffer layer 20B is made of silicon nitride.

In an exemplary implementation, a thickness L12 of the second buffer layer 20B is in the range of 0 angstroms to 1100 angstroms, for example, the thickness L12 of the second buffer layer 20B is 1000 angstroms.

In an exemplary implementation, a refractive index of the second buffer layer 20B is 1.8 to 2.1.

In an exemplary implementation, a first electrode layer 90A includes a pixel electrode and a second electrode layer 90B includes a common electrode; an orthographic projection of the pixel electrode on the base substrate is overlapped with an orthographic projection of the common electrode on the base substrate. In an exemplary implementation, the position of the pixel electrode and the position of the common electrode may be interchanged; alternatively, the common electrode and the pixel electrode are disposed in a same layer, so long as a horizontal electric field can be formed between the pixel electrode and the common electrode to drive the liquid crystal to deflect.

In an exemplary implementation, a material of the first electrode layer 90A and a material of the second electrode layer 90B are the same. For example, the material of the first electrode layer 90A and the material of the second electrode layer 90B include indium tin oxide (ITO). For example, both the first electrode layer 90A and the second electrode layer 90B are made of ITO. The material of the first electrode layer 60 and the material of the second electrode layer 80 are ITO, which can improve the light transmittance of the array substrate.

In an exemplary implementation, a refractive index of the first electrode layer 90A and a refractive index of the second electrode layer 90B are in the range of 2.0 to 2.1.

In an exemplary implementation, a thickness L5 of the first electrode layer 90A may be 720 angstroms to 880 angstroms. Exemplarily, the thickness L5 of the first electrode layer 90A may be 800 angstroms.

In an exemplary implementation, a thickness of the second electrode layer 90B is 360 angstroms to 440 angstroms. Exemplarily, the thickness L7 of the second electrode layer 90B may be 400 angstroms.

In an exemplary implementation, as shown in FIG. 15 and FIG. 16, a thickness L4 of the planarization layer 50 may be 22,950 angstroms to 28,050 angstroms, and exemplarily, the thickness L4 of the planarization layer 50 may be 25,500 angstroms.

In an exemplary implementation, a material of the planarization layer 50 includes an organic material such as an organic resin. For example, a refractive index of the planarization layer 50 may be 1.5 to 1.8.

In an exemplary implementation, as shown in FIG. 15 and FIG. 16, a thickness L6 of the fourth insulation layer 70 is in the range of 720 angstroms to 880 angstroms, and exemplarily, the thickness L6 of the fourth insulation layer 70 may be 800 angstroms.

In an exemplary implementation, a material of the fourth insulation layer 70 includes silicon nitride. For example, the material of the fourth insulation layer 70 is made of silicon nitride. For example, a refractive index of the fourth insulation layer 70 is in the range of 1.6 to 2.0.

In an exemplary implementation, the first buffer layer 20A and the first sub-insulation layer 30A are prepared by two processes, so that there is a clear boundary between the first buffer layer 20A and the first sub-insulation layer 30A. For example, the processes employed by the first buffer layer 20A and the first sub-insulation layer 30A are different, so that the first buffer layer 20A and the first sub-insulation layer 30A have different refractive indices. Exemplarily, a refractive index of the first sub-insulation layer 30A is greater than a refractive index of the first buffer layer 20A, thereby a better transmittance effect can be achieved.

In an exemplary implementation, a thickness of the first buffer layer 20A may be 3,000 angstroms, a thickness of the first sub-insulation layer 30A may be 800 angstroms, a thickness of the second sub-insulation layer 30B may be 400 angstroms, a thickness of the first interlayer insulation layer 40A may be 2,200 angstroms, a thickness of the second interlayer insulating layer 40B may be 1,400 angstroms, and a thickness of the third interlayer insulation layer 40C may be 950 angstroms. A thickness of each film layer may fluctuate in the range of plus or minus 10%. According to this implementation, exemplarily, a material of the first buffer layer 20A includes silicon oxide, a material of the first sub-insulation layer 30A includes silicon oxide, a material of the second sub-insulation layer 30B includes a silicon nitride, a material of the first interlayer insulation layer 40A includes silicon oxide, a material of the second interlayer insulation layer 40B includes a silicon nitride, and a material of the third interlayer insulation layer 40C includes silicon oxide. Thus, a transmittance of the array substrate is higher. According to this implementation, exemplarily, a refractive index of the first buffer layer 20A is in the range of 1.3 to 1.5, a refractive index of the first sub-insulation layer 30A is in the range of 1.3 to 1.5, a refractive index of the second sub-insulation layer 30B is in the range of 1.8 to 2.1, a refractive index of the first interlayer insulation layer 40A is in the range of 1.1 to 1.4, a refractive index of the second interlayer insulation layer 40B is in the range of 1.7 to 1.9, and a refractive index of the third interlayer insulation layer 40C is in the range of 1.1 to 1.4. For example, a transmittance of the non-drive area of the array substrate may be not less than 83% (typ.), for example, 83.6% (typ.).

In an exemplary implementation, a thickness of the first buffer layer 20A may be 3000 angstroms, a thickness of the first sub-insulation layer 30A may be 800 angstroms, a thickness of the second sub-insulation layer 30B may be 400 angstroms, a thickness of the first interlayer insulation layer 40A may be 2,200 angstroms, a thickness of the second interlayer insulation layer 40B may be 1,400 angstroms, and a thickness of the third interlayer insulation layer 40C may be 950 angstroms. According to this implementation, exemplarily, a material of the first buffer layer 20A includes silicon oxide, a material of the first sub-insulation layer 30A includes silicon oxide, a material of the second sub-insulation layer 30B includes silicon nitride, a material of the first interlayer insulation layer 40A includes silicon oxide, a material of the second interlayer insulation layer 40B includes silicon nitride, and a material of the third interlayer insulation layer 40C includes silicon oxide. Thus, the transmittance of the array substrate is higher. According to this implementation, exemplarily, a refractive index of the first buffer layer 20A is in the range of 1.3 to 1.5, a refractive index of the first sub-insulation layer 30A is in the range of 1.3 to 1.5, a refractive index of the second sub-insulation layer 30B is in the range of 1.8 to 2.1, a refractive index of the first interlayer insulation layer 40A is in the range of 1.1 to 1.4, a refractive index of the second interlayer insulation layer 40B is in the range of 1.7 to 1.9, and a refractive index of the third interlayer insulation layer 40C is in the range of 1.1 to 1.4.

In an exemplary implementation, a thickness of the first buffer layer 20A may be 3,000 angstroms, a thickness of the first sub-insulation layer 30A may be 800 angstroms, a thickness of the second sub-insulation layer 30B may be 400 angstroms, a thickness of the first interlayer insulation layer 40A may be 2,200 angstroms, a thickness of the second interlayer insulation layer 40B may be 1,400 angstroms, and a thickness of the third interlayer insulation layer 40C may be 950 angstroms. A thickness of each film layer may fluctuate in the range of plus or minus 10%. The first buffer layer 20A is made of silicon oxide, the first sub-insulation layer 30A is made of silicon oxide, the second sub-insulation layer 30B is made of silicon nitride, the first interlayer insulation layer 40A is made of silicon oxide, the second interlayer insulation layer 40B is made of silicon nitride, and the third interlayer insulation layer 40C is made of silicon oxide. Thus, the transmittance of the array substrate is higher. According to this implementation, exemplarily, a refractive index of the first buffer layer 20A is in the range of 1.3 to 1.5, a refractive index of the first sub-insulation layer 30A is in the range of 1.3 to 1.5, a refractive index of the second sub-insulation layer 30B is in the range of 1.8 to 2.1, a refractive index of the first interlayer insulation layer 40A is in the range of 1.1 to 1.4, a refractive index of the second interlayer insulation layer 40B is in the range of 1.7 to 1.9, and a refractive index of the third interlayer insulation layer 40C is in the range of 1.1 to 1.4.

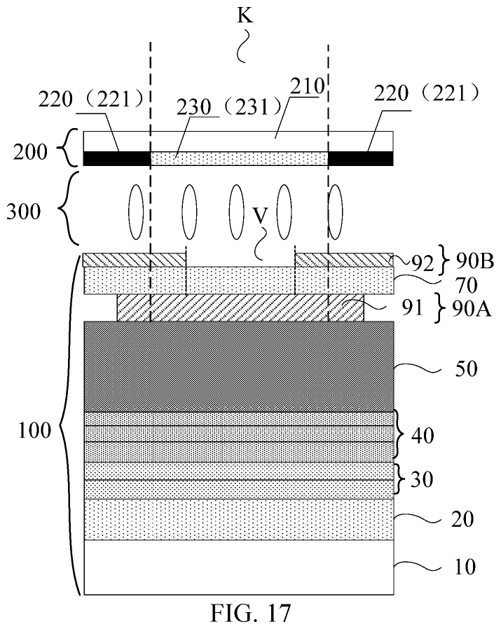

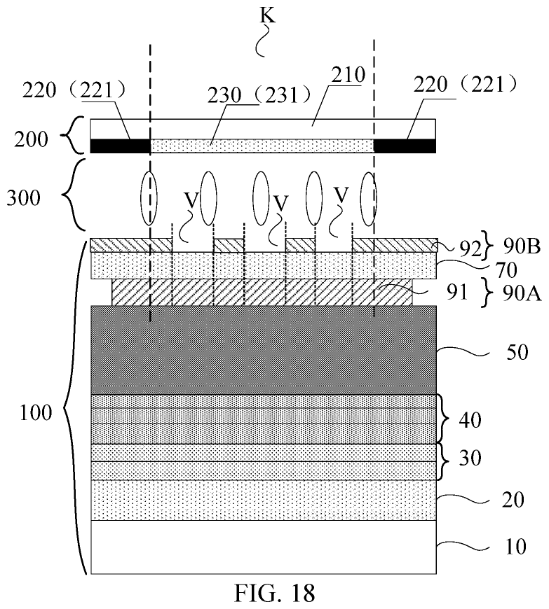

FIG. 17 is a first schematic diagram of a structure of a liquid crystal display panel provided by an embodiment of the present disclosure, and FIG. 18 is a second schematic diagram of a structure of a liquid crystal display panel provided by an embodiment of the present disclosure. As shown in FIG. 17 and FIG. 18, a liquid crystal display panel provided by an embodiment of the present disclosure includes a color filter substrate 200 and an array substrate 100 disposed oppositely, and a liquid crystal layer 300 located between the color filter substrate 200 and the array substrate 100.

The array substrate is the array substrate according to any of the aforementioned embodiments, and has similar implementation principles and implementation effects, which will not be repeated herein.

In an exemplary implementation, the film layer where the first electrode layer 90A and the second electrode layer 90B are located in FIG. 17 and FIG. 18 shows only a pixel electrode and a common electrode, and in an actual application, an insulation material of the fourth insulation layer will be filled between the pixel electrodes of the first electrode layer.

In an exemplary implementation, the liquid crystal layer 300 includes a liquid crystal material, wherein the birefringence of the liquid crystal material is 0.09 to 0.13, so that a light transmittance of the liquid crystal is higher, facilitating the realization of a high transmittance of the display panel.

In an exemplary implementation, the clearing point of the liquid crystal material is greater than or equal to 100° C. For example, the working temperature of the liquid crystal display panel may be −30 to 100° C. The working temperature of the liquid crystal layer of an embodiment of the present disclosure may make the application range of the liquid crystal display panel wider, and solve the problem of ultra-clearing point of a liquid crystal display panel under a high temperature environment.

In an exemplary embodiment, the liquid crystal layer may include a wide temperature liquid crystal polymer.

In an exemplary implementation, as shown in FIG. 17 and FIG. 18, the color filter substrate 200 may include a color filter substrate 210, and a black matrix layer 220 and a light filter layer 230 disposed on the color filter substrate 210.

In an exemplary implementation, as shown in FIG. 17 and FIG. 18, the black matrix layer 220 includes a black matrix 221, and the light filter layer 230 includes a light filter unit 231. The color filter substrate 200 includes a pixel opening region K; the pixel opening region K is surrounded by the black matrix; the light filter unit covers the pixel opening region K. For example, an orthographic projection of the black matrix 221 on the color filter substrate 210 is at least partially overlapped with an orthographic projection of the drive area AA1 on the color filter substrate 210; for example, an orthographic projection of the light filter unit 231 on the color filter substrate 210 is at least partially overlapped with an orthographic projection of the non-drive area AA2 on the color filter substrate.

In an exemplary implementation, the light filter unit 231 may include a red light filter unit, a green light filter unit, and a blue light filter unit. In an exemplary implementation, as shown in FIG. 17 and FIG. 18, an orthographic projection of the black matrix 221 on the base substrate 10 is partially overlapped with an orthographic projection of the pixel electrode 91 on the base substrate 10. For example, an orthographic projection of an edge of the pixel electrode 91 on the base substrate 10 is overlapped with an orthographic projection of the black matrix 221 on the base substrate 10.

In an exemplary implementation, an orthographic projection of the black matrix 221 on the base substrate 10 is partially overlapped with an orthographic projection of the common electrode 92 on the base substrate.

In an exemplary implementation, the common electrode 92 may include one or more slits V. In FIG. 17, illustration is made by taking one slit as an example. Exemplarily, as shown in FIG. 18, the number of slits is three, which facilitates for driving the liquid crystal to fully deflect and improves the display effect. For example, the widths of the slits V are equal.

For example, as shown in FIG. 17 and FIG. 18, the slit V extends in a direction perpendicular to the illustrated cross-sectional direction. For example, an orthographic projection of the slit V on the base substrate 10 is not overlapped with an orthographic projection of the black matrix on the base substrate 10 in a direction perpendicular to an extension direction of the slit V (that is, a horizontal direction of the cross-section illustrated in FIG. 17 and FIG. 18). For example, both side edges of one slit V or multiple slits V as a whole may be exposed in the pixel opening region K in the direction perpendicular to the extension direction of the slit V.

For example, an orthographic projection of the slit V on the base substrate 10 is overlapped with an orthographic projection of the pixel electrode 91 on the base substrate. For example, the orthographic projection of the slit V on the base substrate 10 is within the orthographic projection of the pixel electrode 91 on the base substrate.

The display panel in an embodiment of the present disclosure can not only achieve a larger aperture ratio of the display panel but also has a better display effect.

In an exemplary implementation, a shape of the cross-section of the slit may be rectangular, trapezoidal, or other shape, without any limitation in this disclosure.

In an exemplary embodiment, as shown in FIG. 17 and FIG. 18, a width of the pixel electrode in the horizontal direction is greater than a width of the common electrode slit in the horizontal direction in one extension direction of the pixel.

In an exemplary embodiment, as shown in FIG. 17 and FIG. 18, for example, a width of the pixel electrode in the horizontal direction is greater than a width of the common electrode slit in the horizontal direction in a direction perpendicular to the extension direction of the slit.

In an exemplary implementation, the liquid crystal display panel may include multiple sub-pixels, each sub-pixel includes a common electrode and a pixel electrode, and common electrodes of adjacent sub-pixels are electrically connected. Each sub-pixel includes a light filter unit. A sub-pixel including a red light filter unit may be a red sub-pixel, a sub-pixel including a green light filter unit may be a green sub-pixel, and a sub-pixel including a blue light filter unit may be a blue sub-pixel.

In an exemplary implementation, a sub-pixel may be in a shape of a rectangle, a rhombus, a pentagon, or a hexagon. Three sub-pixels may be arranged side by side horizontally, side by side vertically, or in a manner like a Chinese character “ [symbol] ”, the present disclosure is not limited thereto.

In an exemplary implementation, an area of the array substrate covered by a black matrix layer may be provided with a thin film transistor, a scan line and a data line. The scan line is configured to provide a drive signal to the thin film transistor, and the data line is configured to provide a data signal to the thin film transistor, an extension direction of the scan line intersects with an extension direction of the data line, for example, the extension direction of the scan line may be perpendicular to the extension direction of the data line.

In an exemplary implementation, the film layer structure of the array substrate provided by any of the foregoing embodiments refers to the film layer structure of the area of the array substrate covered by the color filter layer. The film layer structure of the area of the array substrate covered by the black matrix layer may include a base substrate 10, and a first insulation layer 20, a semiconductor layer, a second insulation layer 30, a gate conductive layer, a third insulation layer 40, a source-drain conductive layer, a planarization layer 50, a first electrode layer 90A, a fourth insulation layer 70, and a second electrode layer 90B stacked sequentially on the base substrate 10. Herein, the semiconductor layer may at least include: an active layer of a thin film transistor; the gate conductive layer may at least include: a gate electrode of the thin film transistor and a scan line (gate line); and the source-drain conductive layer may at least include a source-drain electrode of the thin film transistor and a data line.

For example, the black matrix 221 includes a portion extending along a scan line and a portion extending along a data line. For example, the black matrix 221 includes a pixel opening region formed by the intersection of a portion extending along a scan line and a portion extending along a data line. For example, a width of the portion of the black matrix 221 extending along the data line is smaller than a width of the portion extending along the scan line. Specifically, the width of the portion of the black matrix 221 extending along the data line is less than 3 microns, for example 2.8 microns; the width of the portion of the black matrix 221 extending along the scan line is less than 10 microns, for example 8 microns, so that the pixel aperture ratio is large and the overall light transmittance of the display panel is high. Exemplarily, an orthographic projection of the scan line on the base substrate 10 is located within the black matrix 221; and an orthographic projection of the data line on the base substrate 10 is located within the black matrix 221.

In an exemplary implementation, the light filter layer includes a blue light filter unit, a green light filter unit, and a red light filter unit. Among them, wavelengths corresponding to the transmittance peak value and the half-transmittance peak value of the light filter unit may be matched with the film design of the array substrate, to achieve the effect of a high transmittance of the display panel.

In an exemplary implementation, a transmittance peak value of the blue light filter unit corresponds to a wavelength in the range of 445 nm to 465 nm. For example, the transmittance peak value of the blue light filter unit corresponds to a wavelength in the range of 450 nm to 460 nm. Exemplarily, a transmittance peak value of the green light filter unit corresponds to a wavelength of 455 nm.

In an exemplary implementation, one half-transmittance peak value of the blue light filter unit corresponds to a wavelength in the range of 378 nm to 388 nm; the other half-transmittance peak value corresponds to a wavelength in the range of 509 nm to 519 nm. Exemplarily, wavelengths corresponding to the half-transmittance peak value of the blue light filter unit may include 383 nm and 514 nm.

The wavelengths corresponding to the half-transmittance peak value of the blue light filter unit may correspond to two wavelength positions. The wavelength corresponding to the half-transmittance peak value of the blue light filter unit can be understood as the wavelength corresponding to the transmittance at a half of the transmittance peak value.

In an exemplary implementation, a transmittance peak value of the green light filter unit corresponds to a wavelength in the range of 523 nm to 533 nm. Exemplarily, a transmittance peak value of the green light filter unit corresponds to a wavelength of 530 nm.

In an exemplary implementation, one half-transmittance peak value of the green light filter unit corresponds to a wavelength in the range of 473 nm to 483 nm; the other half-transmittance peak value of the green light filter unit corresponds to a wavelength in the range of 598 nm to 608 nm. Exemplarily, wavelengths corresponding to the half-transmittance peak value of the green light filter unit may include 478 nm and 603 nm.

In an exemplary implementation, the wavelengths corresponding to the half-transmittance peak value of the blue light filter unit may correspond to two wavelength positions. The wavelengths corresponding to the half-transmittance peak value of the green light filter unit can be understood as the wavelength corresponding to the transmittance at a half of the transmittance peak value.

In this way, the light filter unit and the film layer design of the array substrate cooperate with each other, which can improve the transmittance of the display panel.

An embodiment of the present disclosure also provides a display device, and the display device includes a backlight source and a liquid crystal display panel.

The liquid crystal display panel is the liquid crystal display panel in accordance with any one of the preceding embodiments, and implementation principles and implementation effects thereof are similar, and will not be repeated herein.

In an exemplary implementation, the light emitting main peak wavelength of the backlight source is in the range of 445 nm to 465 nm; for example, the light emitting main peak wavelength of the backlight source is in the range of 450 nm to 460 nm; exemplarily, the light emitting main peak wavelength of the backlight source is 455 nm. For example, the backlight source also includes a light emitting auxiliary peak, the light emitting auxiliary peak wavelength is in the range of 480 nm to 600 nm; for example, the light emitting auxiliary peak wavelength is in the range of 540 nm to 560 nm. Exemplarily, the auxiliary peak wavelength of the backlight source may be 550 nm.

In the display device provided by an embodiment of the present disclosure, the manufacturing material of the blue light filter unit may be adapted to the light emitting main peak wavelength of the backlight source providing light for the liquid crystal display panel; the manufacturing material of the green light filter unit may be adapted to the light emitting auxiliary peak wavelength of the backlight source providing light for the liquid crystal display panel, so that a person can watch more comfortably under a condition in which a high transmittance of the display panel is ensured. With the cooperation of the display panel and the backlight source provided by an embodiment of the present disclosure, the color points of B are achieved to (0.143 0.101), and the color points under the white screen are achieved to (0.276 0.310).

Table 1 is a brightness comparison table between a liquid crystal display panel 1 and a liquid crystal display panel 2. The liquid crystal display panel 2 is the liquid crystal display panel provided by an embodiment of the present disclosure, and the liquid crystal display panel 1 is a liquid crystal display panel commonly used in the market. Coordinates 1-9 represent the sampling points selected in 9 areas evenly distributed on a display picture. The brightnesses of 9 positions are measured. As shown in Table 1, under the same coordinate, brightness of LCD panel 2 is greater than brightness of LCD panel 1, an average brightness of LCD panel 2 is greater than an average brightness of LCD panel 1, and the average brightness of LCD panel 2 is about 10% higher than the average brightness of LCD panel 1.

TABLE 1

| | Liquid crystal display | Liquid crystal display |
|---|---|---|
| | panel 1 | panel 2 |
| Coordinate 1 | 219.9 | 248.6 |
| Coordinate 2 | 303 | 343 |
| Coordinate 3 | 252.4 | 286 |
| Coordinate 4 | 262.5 | 297 |
| Coordinate 5 | 367 | 398 |
| Coordinate 6 | 294 | 327 |
| Coordinate 7 | 232.6 | 243.5 |
| Coordinate 8 | 335 | 358 |
| Coordinate 9 | 262.4 | 292 |
| Average brightness | 276.7 | 305.7 |

A transmittance of the liquid crystal display panel provided by an embodiment of the present disclosure can be improved by adopting the array substrate provided by the foregoing embodiment, and the picture quality effect can be improved by designing a light filter unit and a backlight source and by using a wide temperature liquid crystal polymer. In an exemplary implementation, the display device may be any product or component with a display function, such as a projection display device, a mobile phone, a tablet computer, a television, a display, a laptop computer, a digital photo frame, and a navigator. It should be noted, when the display device is a projection display device, the array substrate and the display panel with a high transmittance can improve the light efficiency of the projection display device, reduce the heat accumulation caused by strong light irradiating the display panel, and improve the reliability of the projection display device.

The drawings in the present disclosure relate only to the structures involved in the embodiments of the present disclosure, and other structures may refer to conventional designs.

For the sake of clarity, the thickness and size of a layer or a micro structure are enlarged in the accompanying drawings used to describe the embodiments of the present disclosure. It can be understood that when an element such as a layer, film, area or substrate is described as being “on” or “under” another element, this element may be “directly” located “on” or “under” the another element, or an intermediate element may exist.

Although the implementations disclosed in the present disclosure are as above, the described contents are only implementations used for convenience of understanding the present disclosure and are not intended to limit the present disclosure. Any skilled person in the art to which the present invention pertains can make any modifications and changes in forms and details of implementations without departing from the spirit and scope of the present disclosure. However, the patent protection scope of the present disclosure should be subject to the scope defined by the appended claims.

1. An array substrate, comprising: a base substrate, and a first insulation layer, a second insulation layer, a third insulation layer, a planarization layer, a first electrode layer, a fourth insulation layer and a second electrode layer, that are stacked sequentially on the base substrate; wherein,
the third insulation layer comprises a first interlayer insulation layer, a second interlayer insulation layer and a third interlayer insulation layer that are sequentially stacked; the first interlayer insulation layer is located on a side of the second interlayer insulation layer close to the base substrate, and the third interlayer insulation layer is located on a side of the second interlayer insulation layer away from the base substrate;
a material of the first interlayer insulation layer and a material of the third interlayer insulation layer comprise silicon oxide; and a material of the second interlayer insulation layer comprises silicon nitride.

2. The array substrate according to claim 1, wherein a thickness of the first interlayer insulation layer is in a range of 1,980 angstroms to 2,420 angstroms; a thickness of the second interlayer insulation layer is in a range of 1,260 to 1,540 angstroms; and a thickness of the third interlayer insulation layer is in a range of 855 angstroms to 1,045 angstroms.

3. The array substrate according to claim 1, wherein the second insulation layer comprises: a first sub-insulation layer and a second sub-insulation layer, the second sub-insulation layer is located on a side of the first sub-insulation layer away from the base substrate;
a material of the first sub-insulation layer comprises silicon oxide; and a material of the second sub-insulation layer comprises silicon nitride.

4. The array substrate according to claim 2, wherein a thickness of the first sub-insulation layer is in a range of 720 angstroms to 880 angstroms, and a thickness of the second sub-insulation layer is in a range of 360 angstroms to 440 angstroms.

5. The array substrate according to claim 1, wherein the first insulation layer comprises a first buffer layer; a material of the first buffer layer comprises silicon oxide; and a thickness of the first buffer layer is in a range of 2,700 angstroms to 3,300 angstroms.

6. The array substrate according to claim 5, wherein the first insulation layer further comprises a second buffer layer; the second buffer layer is located between the base substrate and the first buffer layer; and a material of the second buffer layer comprises silicon nitride.

7. The array substrate according to claim 1, wherein the first electrode layer comprises a pixel electrode, and the second electrode layer comprises a common electrode;
an orthographic projection of the pixel electrode on the base substrate is overlapped with an orthographic projection of the common electrode on the base substrate.

8. The array substrate according to claim 7, wherein a material of the first electrode layer and a material of the second electrode layer are same and comprise indium tin oxide (ITO).

9. A liquid crystal display panel, comprising: a color filter substrate and the array substrate according to claim 1, that are disposed oppositely, and a liquid crystal layer located between the color filter substrate and the array substrate.

10. The liquid crystal display panel according to claim 9, wherein the liquid crystal layer comprises a liquid crystal material, wherein the liquid crystal material has a birefringence of 0.09 to 0.13; and a clearing point of the liquid crystal material is greater than or equal to 100° C.

11. The liquid crystal display panel according to claim 9, wherein the color filter substrate comprises: a black matrix layer and a light filter layer; the black matrix layer comprises a black matrix, and the light filter layer comprises a light filter unit; the color filter substrate comprises a pixel opening region; the pixel opening region is provided to be surrounded by the black matrix; the light filter unit covers the pixel opening region;
wherein an orthographic projection of the black matrix on the base substrate is partially overlapped with an orthographic projection of a pixel electrode on the base substrate.

12. The liquid crystal display panel according to claim 11, wherein the orthographic projection of the black matrix on the base substrate is partially overlapped with an orthographic projection of a common electrode on the base substrate.

13. The liquid crystal display panel according to claim 11, wherein the common electrode comprises a plurality of slits, and orthographic projections of the plurality of slits on the base substrate have no overlapping region with the orthographic projection of the black matrix on the base substrate, and have an overlapping region with the orthographic projection of the pixel electrode on the base substrate.

14. The liquid crystal display panel according to claim 11, wherein the light filter layer comprises a blue light filter unit, a green light filter unit, and a red light filter unit;
wherein a wavelength corresponding to a transmittance peak value of the blue light filter unit is in a range of 445 nm to 465 nm; a wavelength corresponding to a half-transmittance peak value of the blue light filter unit is in a range of 378 nm to 388 nm, and a wavelength corresponding to another half-transmittance peak value of the blue light filter unit is in a range of 509 nm to 519 nm.

15. The liquid crystal display panel according to claim 14, wherein a wavelength corresponding to a transmittance peak value of the green light filter unit is in a range of 523 nm to 533 nm; a wavelength corresponding to a half-transmittance peak value of the green light filter unit is in a range of 473 nm to 483 nm, and a wavelength corresponding to another half-transmittance peak value of the green light filter unit is in a range of 598 nm to 608 nm.

16. A display device, comprising a backlight source, and the liquid crystal display panel according to claim 9.

17. The display device according to claim 16, wherein a wavelength of a light emitting main peak of the backlight source is in a range of 445 nm to 465 nm; and a wavelength of a light emitting auxiliary peak of the backlight source is in a range of 480 nm to 600 nm.

18. The display device according to claim 16, wherein the display device is a projection display device.

19. The array substrate according to claim 1, wherein refractive indices of the first interlayer insulation layer and the third interlayer insulation layer are smaller than a refractive index of the second interlayer insulation layer.

20. The array substrate according to claim 3, wherein a refractive index of the first sub-insulation layer is smaller than a refractive index of the second sub-insulation layer.
